(19) United States
(12) Patent Application Publication
(10) Pub. No.: US 2015/0060780 A1
(43) Pub. Date: Mar. 5, 2015

(54) ORGANIC LIGHT-EMITTING DISPLAY DEVICE

(71) Applicant: E Ink Holdings Inc., HSINCHU (TW)

(72) Inventors: Cheng-Hang HSU, HSINCHU (TW); Hsing-Yi WU, HSINCHU (TW); Chia-Chun YEH, HSINCHU (TW); Ted-Hong SHINN, HSINCHU (TW); Chih-Hsuan WANG, HSINCHU (TW)

(73) Assignee: E Ink Holdings Inc., HSINCHU (TW)

(21) Appl. No.: 14/195,828

(22) Filed: Mar. 3, 2014

(30) Foreign Application Priority Data
Sep. 5, 2013 (TW) 102132049

(51) Int. Cl. H01L 51/52

(52) U.S. Cl. CPC H01L 51/524
USPC 257/40

(57) ABSTRACT

An organic light-emitting display device includes an active array substrate, an encapsulating layer, an organic light-emitting layer, an absorption layer and a sealant. The encapsulating layer is opposite to the active array substrate, and the encapsulating layer has an inner surface facing the active array substrate. The organic light-emitting layer is disposed on the active array substrate. The absorption layer is configured to absorb at least one of moisture and oxygen, and is positioned on the inner surface of the encapsulating layer. The sealant is disposed between the active array substrate and the encapsulating layer, and encircles the organic light-emitting layer and the absorption layer

### RELATED APPLICATIONS

This application claims priority to Taiwanese application Serial Number 102132049, filed Sep. 5, 2013, the entirety of which is incorporated herein by reference.

### BACKGROUND

1. Technical Field

The present disclosure relates to an organic light-emitting display device.

2. Description of Related Art

There has been rapid progress in organic light-emitting diode (OLED) technologies in recent years. The advantages of OLEDs include high brightness, high contrast and wide view angle. The OLED is a type of light-emitting diode (LED) and has an organic electroluminescent layer therein. The major material of the organic electroluminescent layer is an organic compound. When current passes through the organic compound, the organic compound emits light. The mostly seen problem of OLEDs is the deterioration of the organic light-emitting layer. The organic light-emitting layer reacts with oxygen and moisture easily, and thereby the performance is degraded. Accordingly, the best condition is that the organic light-emitting layer may be completely enclosed inside the OLED device and isolated from the environment. If the penetration of oxygen and moisture into the OLED device may be prevented thoroughly, the lifespan of the OLED device will be extended remarkably. However, it is difficult to develop an assembly technique that thoroughly blocks off oxygen and moisture. Therefore, an important issue in OLED industry is how to develop an effective and reliable encapsulating structure of the OLED.

### SUMMARY

According to one aspect of the present disclosure, an organic light-emitting display device is provided. The organic light-emitting display device is capable of preventing the organic light-emitting layer therein from deterioration and/or damage. The organic light-emitting display device includes an active array substrate, an encapsulating layer, an organic light-emitting layer, an absorption layer and a sealant. The active array substrate is configured to drive the organic light-emitting layer and is opposite to the encapsulating layer. The encapsulating layer has an inner surface facing the active array substrate. The organic light-emitting layer is disposed on the active array substrate. The absorption layer is positioned on the inner surface of the encapsulating layer, and is configured to absorb at least one of moisture and oxygen. The sealant is disposed between the active array substrate and the encapsulating layer, and encircles the organic light-emitting layer and the absorption layer.

According to one embodiment of the present disclosure, the encapsulating layer includes a polymer layer and an inorganic barrier layer. The inorganic barrier layer is configured to block the penetration of at least one of moisture and oxygen. The absorption layer is positioned on the inorganic barrier layer.

According to one embodiment of the present disclosure, the polymer layer is about 0.005 to about 0.5 mm in thickness.

According to one embodiment of the present disclosure, the inorganic barrier layer includes silicon oxide, silicon nitride, or a combination thereof.

According to one embodiment of the present disclosure, the encapsulating layer has a concavity, and the absorption layer is positioned inside the concavity.

According to one embodiment of the present disclosure, the organic light-emitting display device further includes a polymeric planarization layer which covers the absorption layer. The polymeric planarization layer allows at least one of moisture and oxygen to penetrate therethrough.

According to one embodiment of the present disclosure, the absorption layer includes a resin layer, and a plurality of absorbent particles dispersed therein. The absorbent particle contains at least one material selected from the group consisting of calcium chloride, cobalt chloride, calcium sulfate, copper sulfate, calcium oxide, zeolite, silicone, activated aluminum oxide and a combination thereof.

According to one embodiment of the present disclosure, the encapsulating layer is a flexible glass substrate having a thickness of about 10 μm to about 300 μm.

According to one embodiment of the present disclosure, the flexible glass substrate has a concavity, and the absorption layer is positioned inside the concavity.

According to one embodiment of the present disclosure, the organic light-emitting display device further includes a polymeric planarization layer which covers the absorption layer. The polymeric planarization layer allows at least one of moisture and oxygen to penetrate therethrough.

According to one embodiment of the present disclosure, the organic light-emitting display device further includes a patterned spacing layer which is positioned on the flexible glass substrate, and the patterned spacing layer has at least one opening, and the absorption layer is disposed inside the opening.

### BRIEF DESCRIPTION OF THE DRAWINGS

The invention may be more fully understood by reading the following detailed description of the embodiments, with reference made to the accompanying drawings as follows:

FIG. 1A is a top view schematically illustrating an organic light-emitting display device according to one embodiment of the present disclosure;

FIG. 1B is a cross-sectional view along line B-B′ in FIG. 1A;

FIG. 1C schematically depicts an absorption layer according to one embodiment of the present disclosure;

FIG. 2 is a cross-sectional view schematically illustrating an organic light-emitting display device according to another embodiment of the present disclosure;

FIG. 3 is a cross-sectional view schematically illustrating an organic light-emitting display device according to still another embodiment of the present disclosure;

FIG. 4 is a cross-sectional view schematically illustrating an organic light-emitting display device according to still another embodiment of the present disclosure;

FIG. 5 is a cross-sectional view schematically illustrating an organic light-emitting display device according to still another embodiment of the present disclosure;

FIG. 6 is a cross-sectional view schematically illustrating an organic light-emitting display device according to still another embodiment of the present disclosure;

FIGS. 7-9 are cross-sectional views schematically illustrating organic light-emitting display devices according to various embodiments of the present disclosure.

### DETAILED DESCRIPTION

Reference will now be made in detail to the present embodiments of the invention, examples of which are illustrated in the accompanying drawings Wherever possible, the same reference numbers are used in the drawings and the description to refer to the same or like parts.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

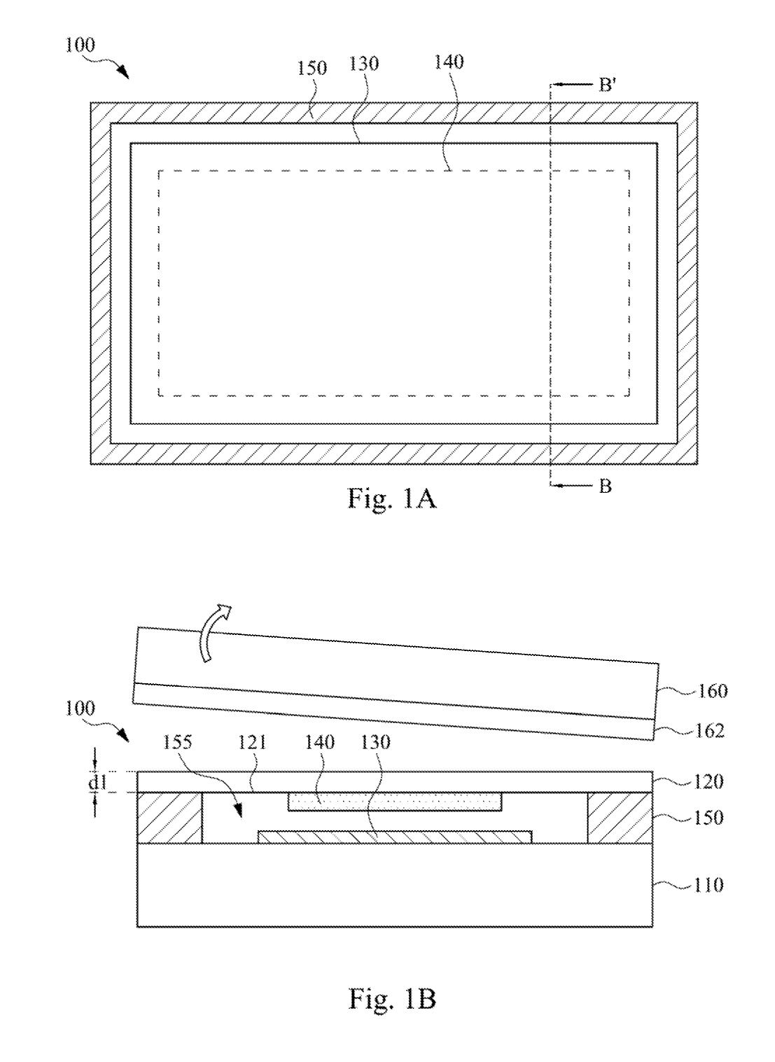

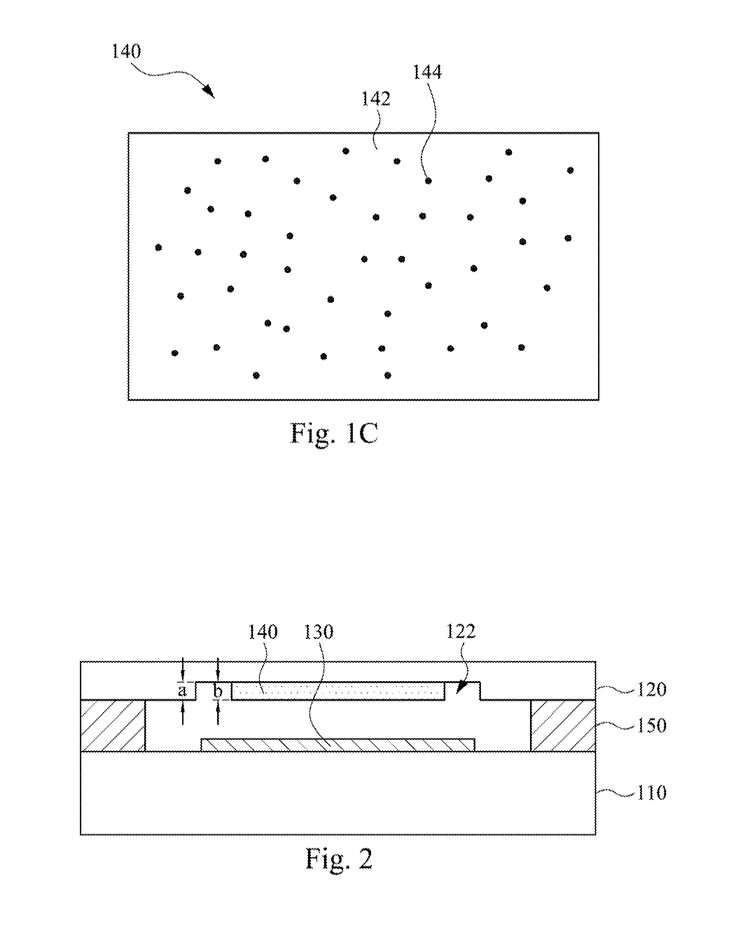

FIG. 1 is a top view schematically illustrating an organic light-emitting display device 100 according to one embodiment of the present disclosure, and FIG. 1B is a cross-sectional view along line B-B′ in FIG. 1A. The organic light-emitting display device 100 includes an active array substrate 110, an encapsulating layer 120, an organic light-emitting layer 130, an absorption layer 140, and a sealant 150.

The active array substrate 110 includes a plurality of pixel structures (not shown in FIGS. 1A and 1B) provided for driving the organic light-emitting layer 130 on the substrate to emit light. There is no specific limitation to the pixel structure of the active array substrate 110, and any pixel structure applicable to the organic light-emitting diode (OLED) may be employed in the present disclosure. In one example, the pixel structure includes a gate line, a data line, a capacitor line, a driving line, and two thin film transistors, which is known in the art.

The organic light-emitting layer 130 is disposed on the active array substrate 110 and is positioned between the active array substrate 110 and the encapsulating layer 120. In general, the organic light-emitting layer 130 includes a plurality of patterned light-emitting layers that emit lights with various colors, such as a red patterned light-emitting layer, a green patterned light-emitting layer, and a blue patterned light-emitting layer. Any material suitable for the organic light-emitting layer 130 may be utilized in the present disclosure. The active array substrate 110 is provided for controlling the light-emitting states of the patterned light-emitting layers such that the organic light-emitting display device 100 displays a predetermined image according to the input data.

The encapsulating layer 120 and the active array substrate 110 are disposed opposite to each other. In particular, the encapsulating layer 120 is substantially parallel to the active array substrate 110, and the encapsulating layer 120 has an inner surface 121 facing the active array substrate 110. In one embodiment, the encapsulating layer 120 is a super thin glass with a thickness d1 of about 10 μm to about 300 μm, specifically about 30 μm to about 100 μm. The super thin glass is flexible and bendable, which is different from the traditional glass in mechanical properties, so that the super thin glass is a type of flexible glass substrate. In some embodiments, the encapsulating layer 120 is a composite-layered structure including a polymer layer and an inorganic barrier layer stacked thereon. More detailed description of the encapsulating layer 120 is provided hereinafter.

The sealant 150 is disposed between the active array substrate 110 and the encapsulating layer 120, and encircles the organic light-emitting layer 130 and the absorption layer 140. In specifics, the sealant 150 is configured to adhere the active array substrate 110 and the encapsulating layer 120 together, and further an enclosed space 155 is formed between the sealant 150, the active array substrate 110 and the encapsulating layer 120. The organic light-emitting layer 130 and the absorption layer 140 are disposed inside the enclosed space 155.

Either moisture or oxygen in the environment has an unfavorable influence on the organic light-emitting layer 130. Many researches show that H₂O molecules and O₂ molecules react with the organic light-emitting layer 130, and thereby deteriorate the organic light-emitting layer 130. Accordingly, the active array substrate 110, the sealant 150, and the encapsulating layer 120 mentioned above are bonded together in an environment free of moisture and oxygen such that the enclosed space is free of moisture and oxygen. Nevertheless, the organic light-emitting layer 130 is still deteriorated since moisture and/or oxygen in the environment penetrate through the sealant 150 and diffuse into the enclosed space 155.

The absorption layer 140 is positioned on the inner surface 121 of the encapsulating layer 120 and provided for absorbing at least one of moisture and oxygen in the enclosed space 155. To be specific, the absorption layer 140 is capable of absorbing moisture and/or oxygen diffused into the enclosed space 155 from the environment, and significantly the absorption layer 140 is not in contact with the organic light-emitting layer 130. In the embodiment illustrated in FIG. 1B, a gap is formed between the absorption layer 140 and the organic light-emitting layer 130. In one embodiment, the absorption layer 140 includes a resin layer 142 and a plurality of absorbent particles 144, as shown in FIG. 1C. The absorbent particles 144 are dispersed in the resin layer 142. The resin layer 142 allows moisture and/or oxygen to diffuse and penetrate therethrough, and reach the absorbent particles 144. Consequently, although the absorbent particles 144 are surrounded by the resin layer 142, the absorbent particles 144 are still capable of absorbing moisture and/or oxygen in the enclosed space. The material of the resin layer 142 may be, for example, ethyl cellulose, epoxy resin, polymethyl methacrylate (PMMA), polymethylglutarimide, (PMGI) or phenol formaldehyde resin (DNQ/Novolac). Various approaches may be utilized to form the absorption layer 140. For instance, screen-printing process, concave plate printing techniques, or other processes may be employed to form the patterned absorption layer 140. In some embodiments, the resin layer 142 includes a photosensitive material, and thus the absorption layer 140 may be formed with a certain pattern by photolithography techniques involving exposure and development processes. The material of the absorbent particle 144 may be, for example, calcium chloride, cobalt chloride, calcium sulfate, copper sulfate, calcium oxide, zeolite, silicone, activated aluminum oxide and a combination thereof.

In one specific example, after the organic light-emitting layer 130 and the absorption layer 140 are formed respectively on the active array substrate 110 and the encapsulating layer 120, the active array substrate 110 with the organic light-emitting layer 130 and the encapsulating layer 120 with the absorption layer 140 are bonded together. For example, liquid glue (the sealant 150) may be coated on the active array substrate 110 (or the encapsulating layer 120). Thereafter, the encapsulating layer 120 (or the active array substrate 110) is attached onto the sealant 150 on the active array substrate 110 for the encapsulating layer 120), and then the liquid glue is cured and converted into the sealant 150. In one embodiment, when the encapsulating layer 120 is a flexible substrate, the encapsulating layer 120 may be temperately adhered to a rigid carrier 160 in advance. For example, the flexible encapsulating layer 120 may be temperately adhered to the rigid carrier 160 by an adhesive layer 162, and then is bonded to the active array substrate 110 through the sealant 150. When the sealant 150 is cured such that the encapsulating layer 120 and the active array substrate 110 are firmly bonded together, the rigid carrier 160 and the adhesive layer 162 are detached and separated from the flexible encapsulating layer 120, and thereby forming the organic light-emitting display device 100 shown in FIG. 1B.

FIG. 2 is a cross-sectional view schematically illustrating an organic light-emitting display device according to another embodiment of the present disclosure. The difference between this embodiment and the one shown in FIG. 1B is that the encapsulating layer 120 has a concavity 122 in which the absorption layer 140 is disposed. When the encapsulating layer 120 is a flexible substrate, the absorption layer 140 on the encapsulating layer 120 possibly comes into contact with the organic light-emitting layer 130 due to the deformation of the encapsulating layer 120. In order to avoid this phenomena, the depth a of the concavity 122 is preferably greater than or equal to the thickness b of the absorption layer 140. Accordingly, the concavity 122 may prevent the absorption layer 140 from touching the organic light-emitting layer 130 when the encapsulating layer 120 is deformed or bended by force.

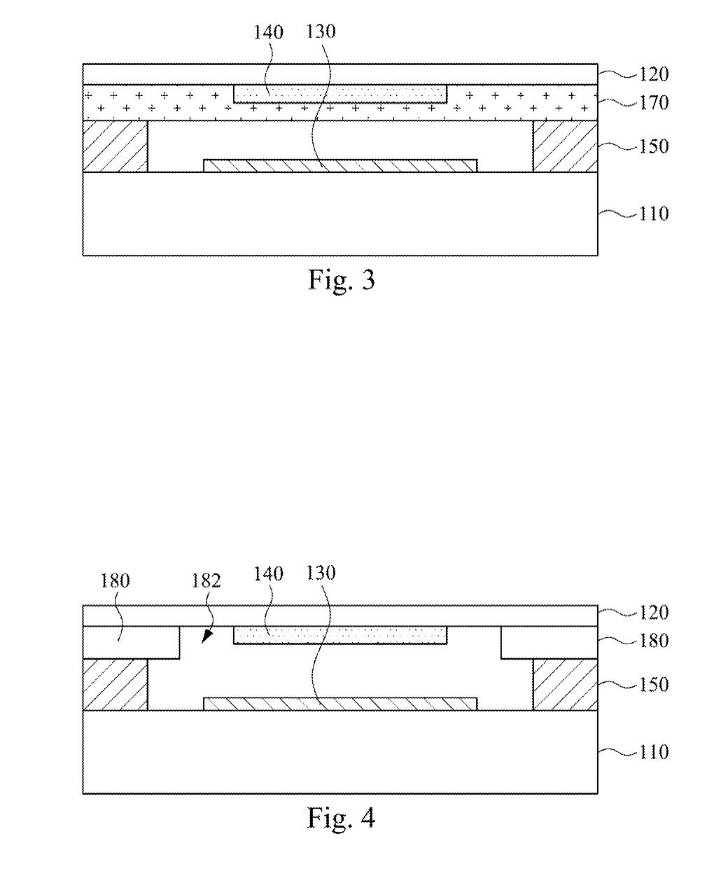

FIG. 3 is a cross-sectional view schematically illustrating an organic light-emitting display device according to still another embodiment of the present disclosure. The present embodiment differs from the one shown in FIG. 1B in that the organic light-emitting display device of this embodiment further includes a polymeric planarization layer 170. The polymeric planarization layer 170 is formed on the absorption layer 140 and covers the absorption layer 140. Moisture and/or oxygen may diffuse and penetrate through the polymeric planarization layer 170 and reach the absorption layer 140. Stated different, the material of the polymeric planarization layer 170 is featured in allowing moisture and/or oxygen to penetrate and pass therethrough. Accordingly, although the polymeric planarization layer 170 covers the absorption layer 140, the absorption layer 140 may still absorb moisture and/or oxygen. Moreover, the polymeric planarization layer 170 may prevent the absorption layer 140 from touching the organic light-emitting layer 130. The absorption layer 140 includes, for example, calcium chloride, cobalt chloride, calcium sulfate, copper sulfate, calcium oxide, zeolite, silicone, activated aluminum oxide and a combination thereof.

FIG. 4 is a cross-sectional view schematically illustrating an organic light-emitting display device according to still another embodiment of the present disclosure. The difference between this embodiment and the one shown in FIG. 1B is that the organic light-emitting display device of this embodiment further includes a patterned spacing layer 180. The patterned spacing layer 180 is disposed on the encapsulating layer 120, and has an opening 182 exposing a portion of the encapsulating layer 120. The absorption layer 140 is formed inside the opening 182. The patterned spacing layer 180 may be made of, for example, a positive photoresist material or a negative photoresist material. In some examples, the opposite sides of the sealant 150 are respectively adhered to the patterned spacing layer 180 and the active array substrate 110. The patterned spacing layer 180 is provided for increasing the distance between the absorption layer 140 and the organic light-emitting layer 130.

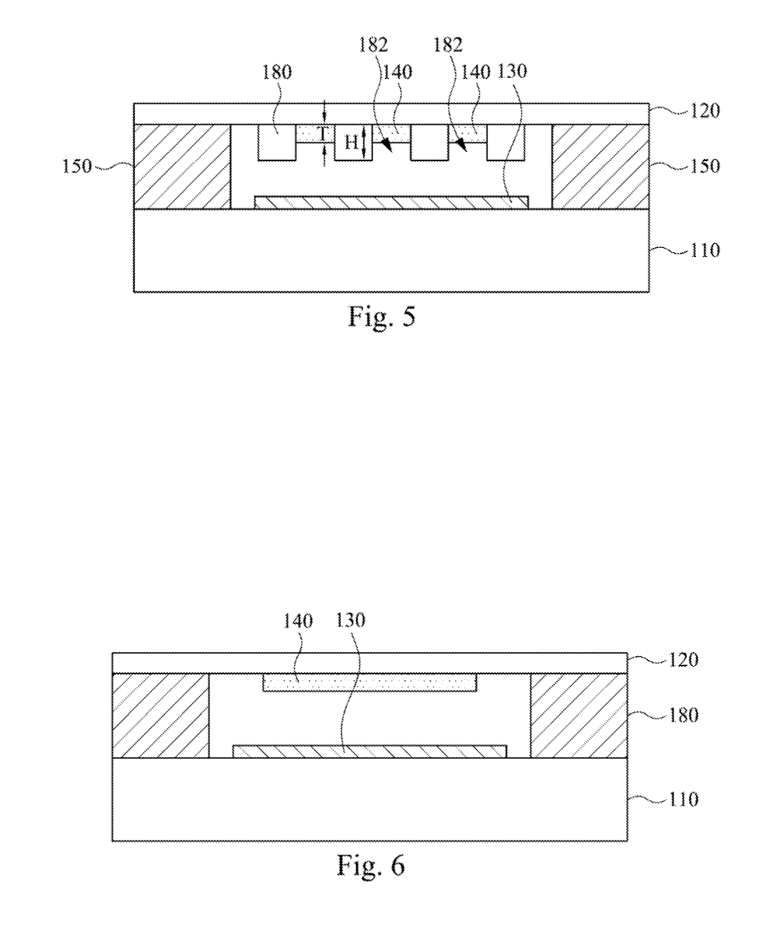

FIG. 5 is a cross-sectional view schematically illustrating an organic light-emitting display device according to still another embodiment of the present disclosure. The difference between this embodiment and the one shown in FIG. 4 is that the patterned spacing layer 180 has a plurality of openings 182, and the patterned spacing layer 180 is positioned right above the organic light-emitting layer 130. Furthermore, the absorption layer 140 is formed in these openings 182, so that the absorption layer 140 has a predetermined pattern. The thickness H of the patterned spacing layer 180 is greater than the thickness T of the absorption layer 140. When the encapsulating layer 120 is deformed or bended, the patterned spacing layer 180 touches the organic light-emitting layer 130 and prevents the absorption layer 140 from directly contact with the organic light-emitting layer 130.

FIG. 6 is a cross-sectional view schematically illustrating an organic light-emitting display device according to still another embodiment of the present disclosure. This embodiment is similar to the one shown in FIG. 4, but differs therefrom in that the patterned spacing layer 180 itself is adhesive and capable of being cured. The patterned spacing layer 180 performs the function of the sealant 150, and replaces the sealant 150 shown in FIG. 4. In other words, the patterned spacing layer 180 functions as the sealant as well in the embodiment shown in FIG. 6.

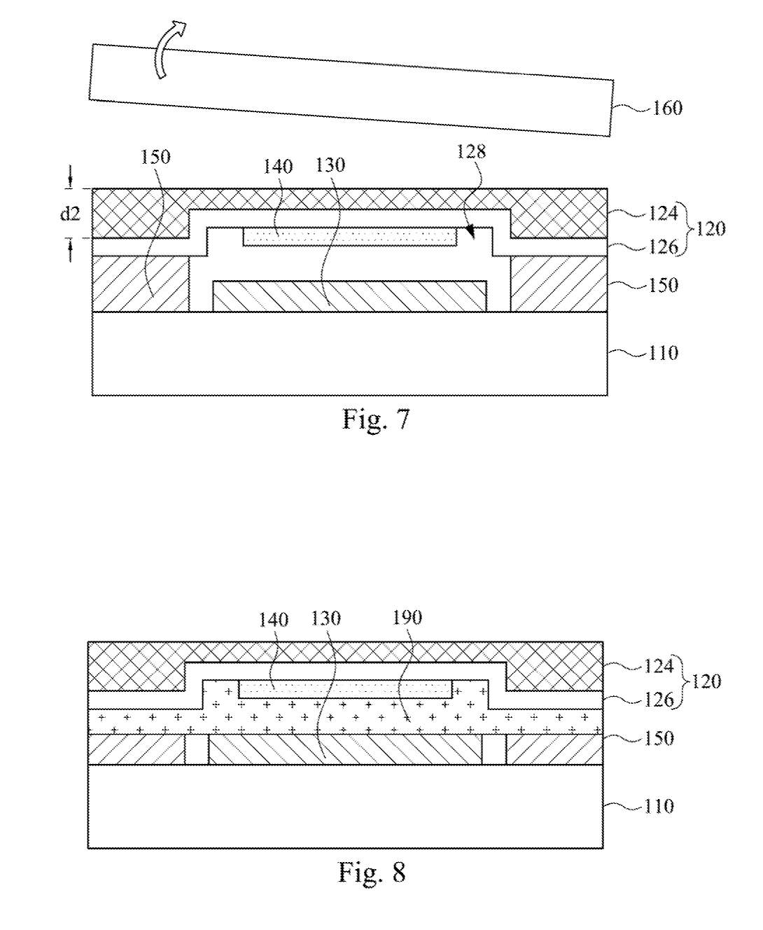

FIGS. 7-9 are cross-sectional views schematically illustrating organic light-emitting display devices according to various embodiments of the present disclosure. In the embodiment shown in FIG. 7, the encapsulating layer 120 includes a polymer layer 124 and an inorganic barrier layer 126. The polymer layer 124 and the inorganic barrier layer 126 are in a stacked structure. The polymer layer 124 is positioned on an outer surface of the organic light-emitting display device, while the inorganic barrier layer 126 is on an inner surface of the organic light-emitting display device. The inorganic barrier layer 126 is provided for preventing at least one of moisture and oxygen from penetrating into the organic light-emitting display device. The absorption layer 140 is formed on the inorganic barrier layer 126. The thickness d2 of the polymer layer 124 may be, for example, about 0.005 to about 0.05 mm. The material of the polymer layer 124 may be, for example, polyimide (PI). The material of the inorganic barrier layer 126 may be, for example, silicon oxide, silicon nitride, or a combination thereof. The encapsulating layer 120 includes a concavity 128 in which the absorption layer 140 is disposed. In specifics, the polymer layer 124 and the inorganic barrier layer 126 may be in sequence formed on a carrier plate 160. Afterwards, the carrier plate 160 with the polymer layer 124 and the inorganic barrier layer 126 is bonded to the active array substrate 110. After the sealant 150 is cured, the carrier plate 160 is removed from the polymer layer 124 so as to form the encapsulating layer 120. The details of the active array substrate 110, the organic light-emitting layer 130, and the sealant 150 may be the same as these described in any of the embodiments hereinbefore, and therefore the description is omitted to avoid repetition.

The embodiment depicted in FIG. 8 is similar to the one shown in FIG. 7, but the difference there between is that the organic light-emitting display device depicted in FIG. 8 further includes a polymeric planarization layer 190. The polymeric planarization layer 190 covers the absorption layer 140 and the concavity 128 (shown in FIG. 7) and makes an even surface. The polymeric planarization layer 190 is positioned between the organic light-emitting layer 130 and the absorption layer 140, and moisture and/or oxygen may penetrate and diffuse through the polymeric planarization layer 190. In other words, the material of the polymeric polymeric planarization layer 190 is featured in allowing moisture and/or oxygen to penetrate and pass therethrough. Therefore, although the polymeric planarization layer 190 covers the absorption layer 140, the absorption layer 140 may still absorb moisture and/or oxygen. Besides, the polymeric planarization layer 190 may prevent the absorption layer 140 from contact with the organic light-emitting layer 130 directly.

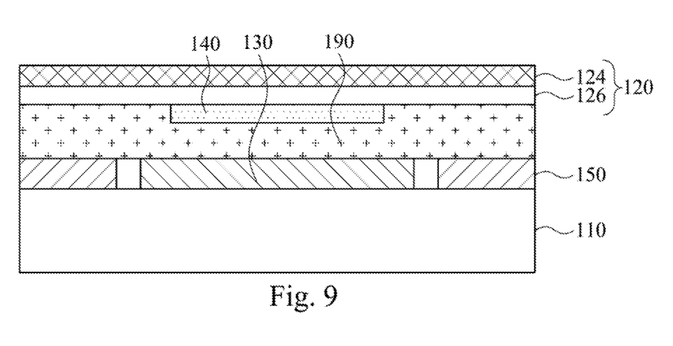

The embodiment depicted in FIG. 9 is similar to the one shown in FIG. 8, but the difference there between is that the encapsulating layer 120 does not include the concavity 128. The absorption layer 140 is formed on the inorganic barrier layer 126. The details of the active array substrate 110, the organic light-emitting layer 130, and the sealant 150 may the same as these described in any of the embodiments hereinbefore, and therefore the description is omitted to avoid repetition.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims.

What is claimed is:

1. An organic light-emitting display device, comprising:
an active array substrate;
an encapsulating layer opposite to the active array substrate and having an inner surface facing the active array substrate;
an organic light-emitting layer disposed on the active array substrate;
an absorption layer configured to absorb at least one of moisture and oxygen, the absorption layer being positioned on the inner surface of the encapsulating layer; and
a sealant disposed between the active array substrate and the encapsulating layer, and encircling the organic light-emitting layer and the absorption layer.

2. The organic light-emitting display device according to claim 1, wherein the encapsulating layer comprises a polymer layer and an inorganic barrier layer configured to block penetration of at least one of moisture and oxygen, wherein the absorption layer is positioned on the inorganic barrier layer.

3. The organic light-emitting display device according to claim 2, wherein the polymer layer has a thickness of approximately between 0.005 mm and 0.5 mm.

4. The organic light-emitting display device according to claim 2, wherein the inorganic barrier layer comprises silicon oxide, silicon nitride, or a combination thereof.

5. The organic light-emitting display device according to claim 1, wherein the encapsulating layer has a concavity, and the absorption layer is positioned inside the concavity.

6. The organic light-emitting display device according to claim 1, further comprising a polymeric planarization layer covering the absorption layer, wherein the polymeric planarization layer allows at least one of moisture and oxygen to penetrate therethrough.

7. The organic light-emitting display device according to claim 1, wherein the absorption layer comprises a resin layer and a plurality of absorbent particles dispersed therein, and the absorbent particle comprises at least one material selected from the group consisting of calcium chloride, cobalt chloride, calcium sulfate, copper sulfate, calcium oxide, zeolite, silicone, activated aluminum oxide and a combination thereof.

8. The organic light-emitting display device according to claim 1, wherein the encapsulating layer is a flexible glass substrate having a thickness of approximately between 10 μm and 300 μm.

9. The organic light-emitting display device according to claim 8, wherein the flexible glass substrate has a concavity, and the absorption layer is positioned inside the concavity.

10. The organic light-emitting display device according to claim 8, further comprising a polymeric planarization layer covering the absorption layer, wherein the polymeric planarization layer allows at least one of moisture and oxygen to penetrate therethrough.

11. The organic light-emitting display device according to claim 8, further comprising a patterned spacing layer positioned on the flexible glass substrate, wherein the patterned spacing layer has at least one opening, and the absorption layer is disposed inside the opening.
